(19) United States
(12) Patent Application Publication
(10) Pub. No.: US 2015/0282302 A1
(43) Pub. Date: Oct. 1, 2015

(54) PREPREG, METAL-CLAD LAMINATE, AND PRINTED WIRING BOARD

(71) Applicant: Panasonic Intellectual Property Management Co., Ltd., Osaka (JP)

(72) Inventors: Takashi HOSHI, Osaka (JP); Hiroharu INOUE, Osaka (JP); Takeshi KITAMURA, Kyoto (JP)

(21) Appl. No.: 14/668,819

(22) Filed: Mar. 25, 2015

(30) Foreign Application Priority Data
Mar. 27, 2014 (JP) 2014-067060

(51) Int. Cl. H05K 1/02; H05K 1/03; B32B 15/14; C08J 5/24; B32B 5/02

(52) U.S. Cl. CPC H05K 1/0271; C08J 5/24; B32B 5/024; B32B 15/14; H05K 1/0373; H05K 1/0366; C08J 2363/00; C08J 2433/00; B32B 2260/046; B32B 2260/021; B32B 2262/101; B32B 2457/08; H05K 2201/0209

(57) ABSTRACT

A prepreg containing: a resin composition; and a woven fabric base material. The resin composition contains: (A) at least one of an epoxy resin having a naphthalene skeleton and a phenolic curing agent having a naphthalene skeleton; (B) a high molecular weight compound having at least structures represented by formulae (1) and (2 ) or at least a structure represented by the formula (2), no unsaturated bond between carbon atoms, and a weight-average molecular weight of 250,000 to 850,000; and (C) an inorganic filler. (C) The inorganic filler is subjected to surface treatment with a silane coupling agent represented by a formula (3).

### TECHNICAL FIELD

The present invention relates to a prepreg, a metal-clad laminate formed by use of the prepreg, and a printed wiring board formed by use of the metal-clad laminate.

### BACKGROUND ART

In a conventional method, a prepreg is formed by impregnating a woven fabric base material with a resin composition containing a thermosetting resin, and drying the woven fabric base material impregnated with the resin composition by heating it until the resin composition becomes in a semi-cured state (for example, see Patent Literatures 1 to 3). To produce a metal-clad laminate, one or more metal foils are provided on the prepreg formed as described above. Furthermore, to produce a printed wiring board, the metal-clad laminate is processed to give a patterned conductor. Then, to produce a package, a semiconductor element is mounted on the printed wiring board and hermetically enclosed.

Examples of packages recently used frequently for a smartphone and a tablet PC include a PoP (Package on Package). The PoP includes a plurality of stacked sub-packages. Therefore, the mounting performance of the sub-packages and the electrical conduction reliability between the sub-packages are important. The mounting performance and the conduction reliability are improved with a decrease in an absolute value of warpage of the package (including the sub-package) at a room temperature and with a decrease in an amount of change in the warpage observed when an ambient temperature is changed from the room temperature to 260° C. Therefore, at present, a substrate material for reducing the warpage of the package has been actively developed.

### PRIOR ART DOCUMENTS

### Patent Literature

Patent literature 1: JP 2006-137942 A

Patent literature 2: JP 2007-138152 A

Patent literature 3: JP 2008-007756 A

### SUMMARY OF THE INVENTION

### Problems to be Resolved by the Invention

At present, as the substrate material for reducing the warpage of the package, there is proposed a material developed for providing high stiffness and a small coefficient of thermal expansion. More specifically, there is proposed a reduction in the warpage of the package with an increase in stiffness and with a decrease in a coefficient of thermal expansion (CTE).

The material having high stiffness and a small coefficient of thermal expansion has been confirmed to exhibit an effect of reducing the warpage of a particular form of the package. However, in a different form of the package, the material exhibits a completely different warpage behavior. This causes a problem of a lack of general versatility.

In a printed wiring board used to produce the package, to provide conduction between patterned conductors formed in different layers, drill processing or laser processing is conducted to form a hole. As a result of forming hole, resin smear may occur in the hole. Therefore, to remove the resin smear, it is necessary to perform a desmear treatment. The desmear treatment is performed by use of permanganate such as potassium permanganate, for example.

However, an increase in the amount of the resin smear to be removed by the desmear treatment (desmear etching amount) may cause the deformation of the hole, the peeling of a copper foil, and/or the like, and hence the conduction reliability is likely to decrease. Therefore, it is necessary to decrease the desmear etching amount.

The present invention has been accomplished in view of the problems, and an object of the present invention is to provide a prepreg, a metal-clad laminate, and a printed wiring board which can reduce warpage of a package and decrease a desmear etching amount.

### Means of Solving the Problems

A prepreg according to the present invention contains a resin composition; and a woven fabric base material. The resin composition contains: (A) at least one of an epoxy resin having a naphthalene skeleton and a phenolic curing agent having a naphthalene skeleton; (B) a high molecular weight compound having at least structures represented by formulae (1) and (2) or at least a structure represented by the formula (2), no unsaturated bond between carbon atoms, and a weight-average molecular weight of 250,000 to 850,000; and (C) an inorganic filler. (C) The inorganic filler is subjected to surface treatment with a silane coupling agent represented by a formula (3).

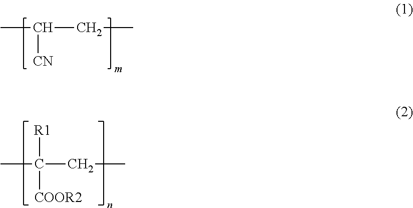

wherein m and n satisfy the following formulae: m:n (molar ratio)=0:1 to0.35:0.65;m+n=1; 0≦m≦0.35;and 0.65≦n≦1, and

R1 is a hydrogen atom or a methyl group, and R2 is a hydrogen atom or an alkyl group.

YSiX₃ (3)

wherein X is a methoxy group or an ethoxy group, and Y has a methacryl group, a glycidyl group, or an isocyanate group at a terminal of an aliphatic alkyl group having carbon atoms of 3 or more and 18 or less.

In the prepreg, a ratio of a loss modulus to a storage modulus is preferably 0.05 or more at a temperature of not more than 60° C. and not less than 200° C. when the prepreg is in a cured state.

In the prepreg, a tensile elongation percentage in a 45°-oblique direction with respect to a warp thread or a weft thread of the woven fabric base material is preferably 5% or more when the prepreg is in a cured state.

A metal-clad laminate according to the present invention includes the prepreg; and a metal foil on the prepreg.

A printed wiring board according to the present invention is prepared by partially removing the metal foil of the metal-clad laminate to give a patterned conductor.

### Effect of the Invention

The present invention can reduce warpage of a package and decrease a desmear etching amount, and improve the conduction reliability of a printed wiring board.

### BRIEF DESCRIPTION OF DRAWINGS

FIG. 1 is a schematic sectional view showing an example of a prepreg;

FIG. 2 is a schematic plan view showing an example of a woven fabric base material;

FIG. 3 is a schematic sectional view showing an example of a metal-clad laminate; and

FIG. 4 is a schematic sectional view showing an example of a printed wiring board.

### DESCRIPTION OF EMBODIMENTS

Embodiments of the present invention will be described below.

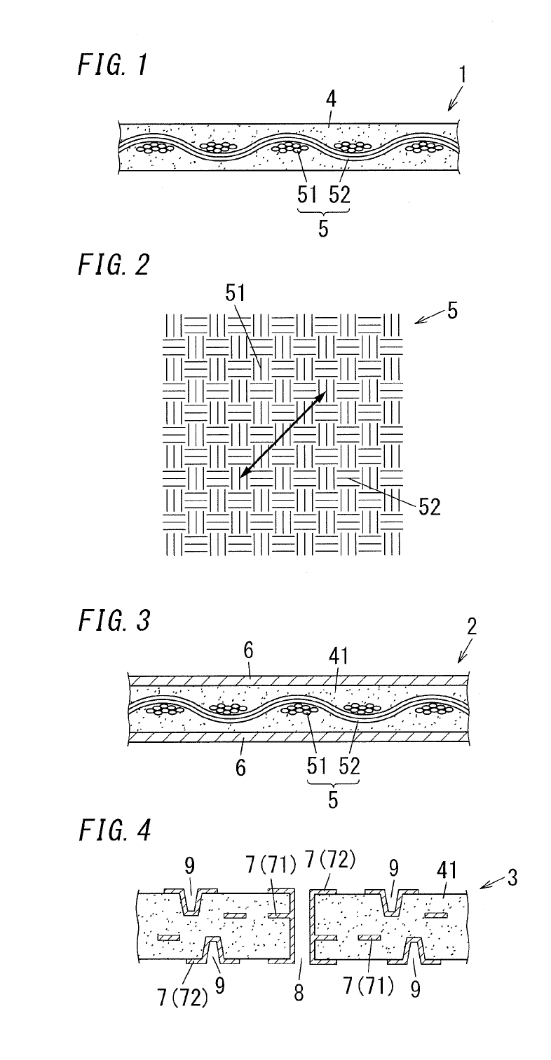

A prepreg 1 of the present embodiment includes a resin composition 4 being in a semi-cured state and a woven fabric base material 5, as shown in FIG. 1. Specifically, the prepreg 1 is formed by impregnating the woven fabric base material 5 with the resin composition 4 being in a varnish state (A-stage state), and drying the woven fabric base material 5 impregnated with the resin composition 4 by heating until the resin composition 4 becomes in a semi-cured state (B-stage state).

The resin composition 4 contains the following components (A), (B), and (C). Particularly, the components (A) and (B) are not compatible but phase-separated in the semi-cured state and cured state of the resin composition 4.

The component (A) is a matrix resin which serves as a high stiffness component. Specifically, the component (A) is at least one of an epoxy resin having a naphthalene skeleton and a phenolic curing agent having a naphthalene skeleton. More specifically, the component (A) may contain both the epoxy resin having a naphthalene skeleton (hereinafter, also referred to as “a naphthalene-type epoxy resin”) and the phenolic curing agent having a naphthalene skeleton (hereinafter, also referred to as “a naphthalene-type phenolic curing agent”). The component (A) may contain an epoxy resin having no naphthalene skeleton and the naphthalene-type phenolic curing agent. The component (A) may contain the naphthalene-type epoxy resin and a phenolic curing agent having no naphthalene skeleton. As described above, at least one of the epoxy resin and the phenolic curing agent has the naphthalene skeleton, and therefore heat resistance of a package for example, solder heat resistance or the like) can be improved.

The component (B) is a low elastic component. Specifically, the component (B) is, for example, an epoxy modified acrylic resin. The component (B) has at least structures represented by formulae (1) and (2) or at least a structure represented by the formula (2).

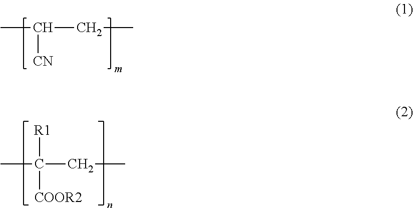

wherein m and n satisfy the following formulae: m:n (molar ratio)=0:1 to 0.35:0.65; m+n=1; 0≦m≦0.35; and 0.65≦n≦1, and

R1 is a hydrogen atom or a methyl group, and R2 is a hydrogen atom or an alkyl group.

More specifically, the component (B) has a main chain having at least the structures represented by the formulae (1) and (2) or at least the structure represented by the formula (2); and an epoxy group bonded to the main chain. Since m and n satisfy the following formulae: m:n (molar ratio)=0:1 to 0.35:0.65; m+n=1; 0≦m≦0.35; and 0.65≦n≦1, the main chain of the component (B) may consist of the structure represented by the formula (2). Except for this, the arrangement order of the structures represented by the formulae (1) and (2) is not particularly limited. In this case, in the main chain of the component (B), the structures represented by the formula (1) may be continuous or non-continuous. The structures represented by the formula (2) may be continuous or non-continuous.

The component (B) does not have an unsaturated bond between carbon atoms such as a double bond and a triple bond. More specifically, in the component (B), carbon atoms are bonded via a saturated bond (single bond). When a prepreg contains a component having an unsaturated bond between carbon atoms, the prepreg loses elasticity and becomes brittle when it is oxidized with time.

The component (B) is a high molecular weight compound having a weight-average molecular weight being within a range of 250,000 to 850,000. The weight-average molecular weight has two significant figures. A numerical value 250,000 or 850,000 rounded off at the third digit (the thousand) is also within the range. The weight-average molecular weight of the component (B) less than 250,000 causes a deterioration in the chemical resistance of the prepreg. In contrast, the weight-average molecular weight of the component (B) greater than 850,000 causes a deterioration in the formability of the prepreg.

Since the resin composition 4 contains the component (B), a cured product of the resin composition 4 is less likely to absorb moisture. Therefore, the moisture resistance of the laminate (for example, a metal-clad laminate and a printed wiring board) can be improved, and the insulation reliability of the laminate can be improved.

The component (C) is an inorganic filler. The inorganic filler is not particularly limited, but examples of the inorganic filler include spherical silica, barium sulfate, silicon oxide powder, crushed silica, burnt talc, barium titanate, titanium oxide, clay, alumina, mica, boehmite, zinc borate, zinc stannate, other metal oxides, and metal hydrates. When the resin composition 4 contains the inorganic filler, the dimensional stability of the laminate can be improved.

The component (C) is subjected to surface treatment with a silane coupling agent represented by the following formula (3).

YSiX₃ (3)

wherein X is a methoxy group or an ethoxy group, and Y has a methacryl group, a glycidyl group, or an isocyanate group at a terminal of an aliphatic alkyl group having carbon atoms of 3 or more and 18 or less.

The silane coupling agent represented by the formula (3) is trifunctional alkoxysilane having an aliphatic alkyl group bonded to a silicon atom. The aliphatic alkyl group has a specific functional group (a methacryl group, a glycidyl group, or an isocyanate group) at the terminal, and has specific carbon atoms. Examples of the silane coupling agent having a methacryl group at the terminal of the aliphatic alkyl group include 3-methacryloxypropyltrimethoxysilane and 3-methacryloxyoctyltrimethoxysilane. Examples of the silane coupling agent having a glycidyl group at the terminal of the aliphatic alkyl group include 3-glycidoxypropyltrimethoxysilane and 3-glycidoxy octyl trimethoxysilane. Examples of the silane coupling agent having an isocyanate group at the terminal of the aliphatic alkyl group include 3-isocyanate propyltriethoxysilane. When the inorganic filler is subjected to surface treatment with the silane coupling agent, the aliphatic alkyl group having the specific carbon atoms is present on the surface of the inorganic filler.

The aliphatic alkyl group functions to relax a stress generated when the prepreg 1 is thermally expanded or thermally shrunk after the prepreg 1 is cured. A stress relaxation layer caused by the aliphatic alkyl group is formed on the surface of the inorganic filler. The inorganic filler having the stress relaxation layer is present in the components (A) and (B), and thereby a stress relaxation action is exhibited for the components (A) and (B) during the thermal expansion or the thermal shrinkage. As a result, the prepreg 1 containing the inorganic filler after cured is less likely to be thermally deformed. There are considered some reasons why the stress relaxation action occurs when the aliphatic alkyl group is present on the surface of the inorganic filler. One of the reasons is that a single bond of the alkyl group can be freely rotated, which can provide also the thermal expansion or thermal shrinkage of the alkyl group of the inorganic filler with the thermal expansion or thermal shrinkage of the components (A) and (B).

Furthermore, the aliphatic alkyl group functions to decrease an etching amount in a desmear treatment on a metal-clad laminate 2 formed by use of the prepreg 1. The aliphatic alkyl group has a methacryl group, a glycidyl group, or an isocyanate group at the terminal, and these functional groups are firmly bonded to the components (A) and (B). Thereby, a desmear etching amount can be decreased. The desmear etching amount can be decreased as compared with the case where the aliphatic alkyl group does not have any functional groups of the methacryl group, glycidyl group, and isocyanate group at the terminal.

The aliphatic alkyl group (Y) in the silane coupling agent represented by the formula (3) has carbon atoms of 3 or more and 18 or less. When the aliphatic alkyl group (Y) has carbon atoms of 2 or less, the elasticity of the prepreg 1 after cured may be increased.

Examples of the method for surface-treating the inorganic filler with the silane coupling agent include a direct treatment method, an integral blend method, and a dry concentrate method. With the view of surface-treating the inorganic filler with the silane coupling agent, an amount of the silane coupling agent to be added to the inorganic filler is not particularly limited. An amount of the silane coupling agent required to form a monomolecular layer of the silane coupling agent on the whole surface layer of the inorganic filler can be calculated according to the following formula (4). A preferable amount of the silane coupling agent to be added is 0.1 to 15 times the calculated value. In this case, the stress relaxation action caused by the inorganic filler is more efficiently exhibited.

W_{C}=W_{F}×S_{F}/S_{C} (4)

W_{C}: an amount of the silane coupling agent required for forming the monomolecular layer (g)

W_{F}: an amount of the inorganic filler to be added (g)

S_{F}: a specific surface area of the inorganic filler (m²/g)

S_{C}: a minimum covering area of the silane coupling agent (m²/g)

The resin composition 4 may contain a curing accelerator. Examples of the curing accelerator include imidazole, a derivative of imidazole, an organic phosphorus compound, a metal soap (e.g., zinc octoate), a secondary amine, a tertiary amine, and a quaternary ammonium salt.

In the resin composition 4, a mass ratio of the component (A) to the component (B) is preferably 90:10 to 50:50.In the component (A), a hydroxyl equivalent of the phenolic curing agent per 1 epoxy equivalent of 1 of the epoxy resin is preferably within a range of 0.2 to 1.1. The content of the component (C) is preferably equal to or less than 80% by mass of the total amount of the resin composition 4. In this case, when the component (C) is subjected to surface treatment with the silane coupling agent, the content of the component (C) is the content of the component (C) containing also the silane coupling agent and subjected to surface treatment with the silane coupling agent.

The resin composition 4 can be prepared by blending the components (A), (B), and (C), and further blending a curing accelerator as required. Furthermore, the resin composition 4 can be diluted with a solvent to prepare a varnish of the resin composition 4. Examples of the solvent include a ketone-type solvent (e.g., acetone, methyl ethyl ketone, and cyclohexanone), an aromatic solvent (e.g., toluene and xylene), and a nitrogen-containing solvent (e.g., dimethylformamide).

The woven fabric base material 5 is not particularly limited so long as it is a woven fabric in which warp threads 51 and weft threads 52 are interlaced at an almost right angle like a plain-woven fabric shown in FIG. 2. Examples of the woven fabric base material 5 include: a woven fabric made of inorganic fibers such as glass cloth; and a woven fabric made of organic fibers such as aramid cloth. The woven fabric base material 5 preferably has a thickness of 10 to 200 μm.

The prepreg 1 can be produced by impregnating the woven fabric base material 5 with the resin composition 4 and drying the woven fabric base material 5 impregnated with the resin composition 4 by heating until the resin composition becomes in a semi-cured state.

In the prepreg 1, a ratio of a loss modulus to a storage modulus (loss tangent tan δ= loss modulus/storage modu(us) is preferably 0.05 or more at a temperature of not more than 60° C. and not less than 200° C. when the prepreg 1 is in a cured state. As described above, since the loss tangent has two peaks, the prepreg 1 can have both features of the high stiffness of the component (A) and the low elasticity of the component (B). The loss tangent can be measured by use of a dynamic mechanical analyzer.

In the prepreg 1, a tensile elongation percentage in a 45°-oblique direction (for example, a direction of a double-headed arrow in FIG. 2) with respect to the warp thread 51or the weft thread 52 of the woven fabric base material 5 is preferably 5% or more when the prepreg 1 is in a cured state. For measurement of the tensile elongation percentage, a specimen in which a single prepreg 1 is in a cured state (C-stage state) is usually used. There may be used a specimen in which a plurality of prepregs 1 are stacked so that directions of a warp thread 51 and a weft thread 52 of one of the prepregs are respectively identical to those of another prepregs, and the prepregs are in a cured state. The tensile elongation percentage can be measured in the following tensile test. First, alength (L₀) of a specimen in the 45°-oblique direction with respect to the warp thread 51 or the weft thread 52 is measured before the tensile test. In this case, the width of the specimen is adjusted to 5 mm. Next, the specimen is elongated in the 45°-oblique direction with respect to the warp thread 51 or the weft thread 52 at a velocity of 5 mm/min by use of a tensile tester. A length (L) of the specimen at the moment of rupture is measured. The tensile elongation percentage can be calculated according to the following formula (5).

Tensile elongation percentage (%)={(L−L₀)/L₀}×100 (5)

The tensile elongation percentage obtained as described above is 5% or more, which makes it possible to further reduce the warpage of the package.

The metal-clad laminate 2 of the present embodiment is formed by stacking a metal foil 6 on the prepreg 1. Specifically, as shown in FIG. 3, the metal foil 6 is bonded to the surface of an insulating layer 41 formed by curing the prepreg 1, to form the metal-clad laminate 2. In this case, the metal-clad laminate 2 may be formed by providing the metal foil 6 on one side or both sides of the single prepreg 1, or by stacking a plurality of prepregs 1 to prepare a laminate and providing the metal foil 6 on one side or both sides of the laminate. The prepreg 1 being in a semi-cured state serves as the insulating layer 41 being in a cured state as described above. Examples of the metal foil 6 include a copper foil. The formation of the laminate can be performed by applying heat and pressure by use of a multistage vacuum press and a double belt, for example.

A printed wiring board 3 of the present embodiment includes the metal-clad laminate 2 having a patterned conductor 7 formed by partially removing the metal foil 6 of the metal-clad laminate 2. The patterned conductor 7 can be formed by, for example, a subtractive method. An example of the printed wiring board 3 is shown in FIG. 4. The printed wiring board 3 is a multi-layer printed wiring board having the patterned conductor 7 formed by the subtractive method and multi-layered by a buildup method. The patterned conductor 7 formed in the insulating layer 41 is an internal patterned layer 71. The patterned conductor 7 formed on the external surface of the insulating layer 41 is an external patterned layer 72. In FIG. 4, the illustration of the woven fabric base material 5 is omitted.

With the view of forming the patterned conductor 7, a hole is formed in the insulating layer 41 in order to provide interlayer connection. The interlayer connection provides electrical conduction between the patterned conductors 7 formed in different layers. The hole may be a penetration hole (through hole) penetrating the printed wiring board 3, or a non-penetration hole (blind hole) which does not penetrate the printed wiring board 3. As shown in FIG. 4, a via hole 8 can be formed by plating an inner surface of the penetration hole, and a blind via hole 9 can be formed by plating an inner surface of the non-penetration hole. Although omitted from the drawing, a buried via hole may be formed. The hole has an inner diameter within a range of 0.01 to 0.20 mm, for example. The hole has a depth within a range of 0.02 to 0.80 mm, for example. The hole can be formed by drill processing or laser processing.

Since the insulating layer 41 contains the inorganic filler subjected to surface treatment with the silane coupling agent, and the functional group located at the terminal of the aliphatic alkyl group of the silane coupling agent is the methacryl group, the glycidyl group, or the isocyanate group, the desmear etching amount can be decreased. Even when resin smear has occurred, the resin smear present in the hole can be further removed by cleaning the inside of the hole according to a desmear treatment such as chemical hole cleaning. This can eliminate conduction failure caused by the resin smear, and improve conduction reliability.

Since the insulating layer 41 contains the inorganic filler subjected to surface treatment with the silane coupling agent, and the aliphatic alkyl group of the silane coupling agent functions as a stress relaxation layer, the printed wiring board 3 can have low elasticity and yet have a small coefficient of thermal expansion, and can also have high elongation characteristics.

Then, a semiconductor device is mounted on the printed wiring board 3 and hermetically enclosed. Consequently, a package such as FBGA (Fine pitch Ball Grid Array) can be produced. The package can be used as a sub-package and these sub-packages can be stacked to produce a package such as PoP (Package on Package). As described above, various forms of packages can be produced. The components (A) and (B) reduce the warpage of every package and improve the heat resistance. More specifically, since the stiffness of the package can be improved by the component (A) and the stress can be relaxed by the elasticity lowered by the component (B), the warpage of the package can be generally reduced without depending on the form of the package. Furthermore, the heat resistance of the package can also be particularly improved by the component (A).

### EXAMPLES

Hereinafter, the present invention will be specifically described with Examples.

### <Blended Raw Materials>

Component (A)

(A-1) naphthalene-type epoxy resin (trade name “HP9500” available from DIC Corporation)

(A-2) naphthalene-type phenolic curing agent (trade name “HPC9500” available from DIC Corporation)

Component (B)

(B-1) epoxy modified acrylic resin (trade name “SG-P3 improved 215” available from Nagase ChemteX Corporation)

This has structures represented by the formulae (1) and (2) (R1 is a hydrogen atom or a methyl group, and R2 is a methyl group, an ethyl group, or a butyl group), no unsaturated bond between carbon atoms, and a weight-average molecular weight of 850,000.

(B-2) epoxy modified acrylic resin (trade name “SG-P3 improved 215Mw2” available from Nagase ChemteX Corporation)

This has structures represented by the formulae (1) and (2) (R1 is a hydrogen atom or a methyl group, and R2 is a methyl group, an ethyl group, or a butyl group), no unsaturated bond between carbon atoms, and a weight-average molecular weight of 600,000.

(B-3) epoxy modified acrylic resin (trade name “SG-P3 improved 215Mw 1” available from Nagase ChemteX Corporation)

This has structures represented by the formulae (1) and (2) (R1 is a hydrogen atom or a methyl group, and R2 is a methyl group, an ethyl group, or a butyl group), no unsaturated bond between carbon atoms, and a weight-average molecular weight of 250,000.

Component (C)

(C-1) GPTMS surface-treated silica

This is spherical silica (trade name “SO-25R” available from Admatechs Company Limited) subjected to surface treatment with 3-glycidoxypropyltrimethoxysilane (trade name “KBM-403” available from Shin-Etsu Chemical Co., Ltd., abbreviated to “(GPTMS”).

(C-2) MPTMS surface-treated silica

This is spherical silica (trade name “SO-25R” available from Admatechs Company Limited) subjected to surface treatment with 3-methacryloxypropyltrimethoxysilane (trade name “KBM-503” available from Shin-Etsu Chemical Co., Ltd., abbreviated to “MPTMS”).

(C-3) IPTES surface-treated silica

This is spherical silica (trade name “SO-25R” available from Admatechs Company Limited) subjected to surface treatment with 3-isocyanate propyltriethoxysilane (trade name “KBE-9007” available from Shin-Etsu Chemical Co., Ltd., abbreviated to “IPTES”).

(C-4) GOTMS surface-treated silica

This is spherical silica (trade name “SO-25R” available from Admatechs Company Limited) subjected to surface treatment with 3-glycidoxy octyl trimethoxysilane (trade name “KBM-4803” available from Shin-Etsu Chemical Co., Ltd., abbreviated to “GOTMS”).

(C-5) MOTMS surface-treated silica

This is spherical silica (trade name “SO-25R” available from Admatechs Company Limited) subjected to surface treatment with 3-methacryloxyoctyltrimethoxysilane (trade name “KBM-5803” available from Shin-Etsu Chemical Co., Ltd., abbreviated to “MOTMS”).

(C-6) spherical silica (trade name “SO-25R” available from by Admatechs Company Limited) which is not subjected to surface treatment

(C-7) DTMS surface-treated silica

This is spherical silica (trade name “SO-25R” available from Admatechs Company Limited) subjected to surface treatment with decyltrimethoxysilane (trade name “KBM-3103” available from Shin-Etsu Chemical Co., Ltd., abbreviated to “DTMS”).

(C-8) HTMS surface-treated silica

This is spherical silica (trade name “SO-25R” available from Admatechs Company Limited) subjected to surface treatment with hexyltrimethoxysilane (trade name “KBM-3063” available from Shin-Etsu Chemical Co., Ltd., abbreviated to “HTMS”).

Except for (C-6), the surface treatment was performed under a condition where a silane coupling agent was 1 part by mass per 100 parts by mass of an inorganic filler.

### (Other)

Curing accelerator (imidazole, and trade name “2E4MZ” available from Shikoku Chemicals Corporation)

Woven fabric base material (glass cloth, and trade name “1037” available from Asahi Kasei E-materials Corporation, thickness: 27 μm)

### (Prepreg)

The components (A), (B), and (C), and the curing accelerator were blended in blending amounts (parts by mass) shown in Table 1. Furthermore, the resultant resin composition was diluted with a solvent (methyl ethyl ketone) to prepare a varnish of the resin composition.

Next, the woven fabric base material was impregnated with the resin composition so that a resultant prepreg had a thickness of 30 μm after the resin composition was cured. The woven fabric base material impregnated with the resin composition was dried by heating at 130° C. for 6 min until the resin composition became in a semi-cured state. Consequently, the prepreg was produced.

### (Metal-Clad Laminate)

Two prepregs were stacked to form a laminate, and a copper foil (thickness: 12 μm) as a metal foil was provided on each of both sides of the laminate. The resultant laminate was hot-formed at 220° C. for 60 min while being pressed at 2.94 MPa (30 kgf/cm²) under a vacuum condition. Consequently, as a metal-clad laminate, a copper-clad laminate (CCL) was produced.

### <Evaluation Items>

The following physical properties were evaluated. The results are shown in Table 1.

### (Loss Tangent (tan δ) and Glass Transition Temperature (Tg))

A single prepreg was used, and treated so that the prepreg was in a cured state. The prepreg was then cut into a specimen having a size of 50 mm×5 mm. The loss tangent (tan δ) of the specimen was measured by use of a dynamic mechanical spectrometer (trade name “DMS6100” available from SII NanoTechnology Inc.) under a condition of a rate of temperature increase of 5° C./min. A temperature providing a maximum loss tangent (tan δ) was defined as a glass transition temperature (Tg).

### (Elastic Modulus)

Eight prepregs were stacked, and hot-formed while being pressed so that the prepregs were in a cured state, to manufacture a specimen. The elastic modulus at 25° C. of the specimen was measured by use of a dynamic mechanical spectrometer (trade name “DMS6100” available from SII NanoTechnology Inc).

### (Coefficient of Thermal Expansion (CTE))

A single prepreg was used, and treated so that the prepreg was in a cured state, to manufacture a specimen. A coefficient of thermal expansion (CTE) in the direction of the sheet thickness of the specimen was measured by a TMA method (Thermal mechanical analysis method) according to JIS C 6481 at a temperature of less than a glass transition temperature (Tg) of a cured product of the resin composition of the specimen. A thermal mechanical analyzer (trade name “TMA6000” available fom SII NanoTechnology Inc.) was used for measurement.

### (Tensile Elongation Percentage)

A single prepreg was used, and treated so that the prepreg was in a cured state, to produce a specimen. A tensile elongation percentage was measured in the following tensile test. First, alength (L₀) of the specimen in a 45°-oblique direction with respect to a warp thread or a weft thread was measured before the tensile test. In this case, the width of the specimen was adjusted to 5 mm. Next, the specimen was elongated in the 45°-oblique direction with respect to the warp thread or the weft thread at a velocity of 5 mm/min by use of a tensile tester (trade name “Autograph AGS-X” available from Shimadzu Corporation). A length (L) of the specimen at the moment of rupture was measured. The tensile elongation percentage was calculated according to the following formula.

Tensile elongation percentage (%)={(L−L₀)/L₀}×100

### (Peel Strength)

A peel strength (peel intensity or copper foil adhesion strength) of the metal foil on the surface of the metal-clad laminate was measured with reference to JIS C 6481. In this case, a metal-clad laminate having a width of 20 mm and a length of 100 mm was used as a test specimen, and a pattern having a width of 10 mm and a length of 100 mm was formed on the test specimen by etching. The pattern was peeled at a velocity of 50 mm/min by use of a tensile tester (trade name “Autograph AGS-X” available from Shi adzu Corporation). The peel intensity (kgf/cm²) in this case was measured as the peel strength.

### (Package Warpage Amount)

To measure a package warpage amount, a simple FC mounting package (size: 16 mm×16 mm) was first produced by mounting a flip chip (FC) on a substrate by bonding with a stiffener (trade name “HCV5313HS” available from Panasonic Corporation). Here, as the FC, a Si chip having a size of 15.06 mm×15.06 mm×0.1 mm and carrying 4356 solder balls (height: 80 μm) was used. A substrate prepared by removing the metal foil of the metal-clad laminate was used.

Next, the warpage of the FC mounting package was measured by use of a warpage measurement system (trade name “THERMOIRE PS200” available from AKROMETRIX Co.) based on the shadow moire measurement principle. The package warpage amount was a difference between a maximum value and a minimum value of warpage amounts measured in a process in which the FC mounting package was heated from 25° C. to 260° C. and then cooled down to 25° C.

### (Desmear Etching Amount)

A desmear etching amount was calculated from a difference between the mass of a specimen before being subjected to a desmear treatment and the mass of the specimen after being subjected to the desmear treatment by use of permanganate.

Specifically, a metal foil of a metal-clad laminate having a size of 10 cm×10 cm was removed to manufacture a specimen, and the desmear etching amount was calculated from a difference (unit: mg/cm²) between the mass (initial mass) of the specimen before being subjected to the desmear treatment and the mass of the specimen after being subjected to the desmear treatment under the following condition.

After the specimen was dried at 100° C. for 1 hour and at 150° C. for 1 hour, and air-cooled in a desiccator for 1 day, the initial mass was measured.

The desmear treatment was performed as follows. First, the specimen after the initial mass was measured was swollen for 5 minutes by “MLB211” and “CupZ” available from Rohm & Haas, and then subjected to a micro etching treatment for 6 minutes by “MLB213A-1” and “MLB213B-1” available from Rohm & Haas. Next, the specimen was neutralized for 5 minutes by “MLB216-2” available from Rohm & Haas, and then dried at 100° C. for 1 hour and at 150° C. for 1 hour. The specimen was then air-cooled in a desiccator for 1 day, and the mass of the specimen after the desmear treatment was measured.

TABLE 1

| | | Examples | | | | | | | | | | | | |
|---|---|---|---|---|---|---|---|---|---|---|---|---|---|---|
| | | 1 | 2 | 3 | 4 | 5 | 6 | 7 | 8 | 9 | 10 | 11 | 12 | 13 |
| Blended raw materials | | | | | | | | | | | | | | |
| and evaluation items | | | | | | | | | | | | | | |
| (A) | (A-1) | 41.67 | 41.67 | 41.67 | 41.67 | 41.67 | 41.67 | 41.67 | 41.67 | 41.67 | 41.67 | 41.67 | 41.67 | 41.67 |
| | Naphthalene- | | | | | | | | | | | | | |
| | type epoxy | | | | | | | | | | | | | |
| | resin | | | | | | | | | | | | | |
| | (A-2) | 28.33 | 28.33 | 28.33 | 28.33 | 28.33 | 28.33 | 28.33 | 28.33 | 28.33 | 28.33 | 28.33 | 28.33 | 28.33 |
| | Naphthalene- | | | | | | | | | | | | | |
| | type | | | | | | | | | | | | | |
| | phenolic | | | | | | | | | | | | | |
| | curing agent | | | | | | | | | | | | | |
| (B) | (B-1) | 30 | 30 | 30 | 30 | 30 | | | 30 | 30 | 30 | | | |
| | Epoxy | | | | | | | | | | | | | |
| | modified | | | | | | | | | | | | | |
| | acrylic resin | | | | | | | | | | | | | |
| | (Mw: | | | | | | | | | | | | | |
| | 850,000) | | | | | | | | | | | | | |
| | (B-2) | | | | | | 30 | | | | | 30 | 30 | 30 |
| | Epoxy | | | | | | | | | | | | | |
| | modified | | | | | | | | | | | | | |
| | acrylic resin | | | | | | | | | | | | | |
| | (Mw: | | | | | | | | | | | | | |
| | 600,000) | | | | | | | | | | | | | |
| | (B-3) | | | | | | | 30 | | | | | | |
| | Epoxy | | | | | | | | | | | | | |
| | modified | | | | | | | | | | | | | |
| | acrylic resin | | | | | | | | | | | | | |
| | (Mw: | | | | | | | | | | | | | |
| | 250,000) | | | | | | | | | | | | | |
| Curing accelerator | | | | | | | | | | | | | | |
| (imidazole) | | 0.04 | 0.04 | 0.04 | 0.04 | 0.04 | 0.04 | 0.04 | 0.04 | 0.04 | 0.04 | 0.04 | 0.04 | 0.04 |
| (C) | (C-1) | 50 | | | | | | | | | | 100 | 150 | 200 |
| | GPTMS | | | | | | | | | | | | | |
| | surface- | | | | | | | | | | | | | |
| | treated silica | | | | | | | | | | | | | |
| | (C-2) | | 50 | | | | | | | | | | | |
| | MPTMS | | | | | | | | | | | | | |
| | surface- | | | | | | | | | | | | | |
| | treated silica | | | | | | | | | | | | | |
| | (C-3) | | | 50 | | | 50 | 50 | 100 | 150 | 200 | | | |
| | IPTES | | | | | | | | | | | | | |
| | surface- | | | | | | | | | | | | | |
| | treated silica | | | | | | | | | | | | | |
| | (C-4) | | | | 50 | | | | | | | | | |
| | GOTMS | | | | | | | | | | | | | |
| | surface- | | | | | | | | | | | | | |
| | treated silica | | | | | | | | | | | | | |
| | (C-5) | | | | | 50 | | | | | | | | |
| | MOTMS | | | | | | | | | | | | | |
| | surface- | | | | | | | | | | | | | |
| | treated silica | | | | | | | | | | | | | |
| | (C-6) | | | | | | | | | | | | | |
| | SO-25R | | | | | | | | | | | | | |
| | (C-7) | | | | | | | | | | | | | |
| | DTMS | | | | | | | | | | | | | |
| | surface- | | | | | | | | | | | | | |
| | treated silica | | | | | | | | | | | | | |
| | (C-8) | | | | | | | | | | | | | |
| | HTMS | | | | | | | | | | | | | |
| | surface- | | | | | | | | | | | | | |
| | treated silica | | | | | | | | | | | | | |
| Total (part by mass) | | 150 | 150 | 150 | 150 | 150 | 150 | 150 | 200 | 250 | 300 | 200 | 250 | 300 |
| Evaluation | Peak top | 23 | 24 | 25 | 24 | 22 | 25 | 24 | 26 | 24 | 23 | 23 | 24 | 25 |
| of | temperature | | | | | | | | | | | | | |
| physical | satisfying tan | 254 | 256 | 258 | 255 | 256 | 252 | 251 | 258 | 258 | 258 | 256 | 254 | 255 |
| properties | δ ≧0.05 (° C.) | | | | | | | | | | | | | |
| | Elastic | 1.4 | 1 | 1.1 | 0.5 | 0.4 | 1 | 1 | 1.1 | 1.32 | 1.1 | 1 | 1.5 | 1.9 |
| | modulus | | | | | | | | | | | | | |
| | [GPa] | | | | | | | | | | | | | |
| | Coefficient of | 5.7 | 5.6 | 5.8 | 5.7 | 5.5 | 5.4 | 5.4 | 6 | 6.1 | 6.1 | 5.5 | 5.7 | 5.6 |
| | thermal | | | | | | | | | | | | | |
| | expansion | | | | | | | | | | | | | |
| | [CTE ppm/ | | | | | | | | | | | | | |
| | ° C.] | | | | | | | | | | | | | |
| | Tensile | 22 | 24 | 23 | 25 | 24 | 26 | 23 | 18 | 10 | 5 | 22 | 19.5 | 16 |
| | elongation | | | | | | | | | | | | | |
| | percentage | | | | | | | | | | | | | |
| | [%] | | | | | | | | | | | | | |
| | Peel strength | 0.55 | 0.54 | 0.55 | 0.53 | 0.53 | 0.55 | 0.55 | 0.55 | 0.55 | 0.55 | 0.46 | 0.42 | 0.4 |
| | [kgf/cm²] | | | | | | | | | | | | | |
| | Package | 465 | 455 | 456 | 436 | 430 | 465 | 435 | 432 | 438 | 512 | 425 | 426 | 430 |
| | warpage | | | | | | | | | | | | | |
| | amount [μm] | | | | | | | | | | | | | |
| | Desmear | 0.20 | 0.19 | 0.22 | 0.23 | 0.22 | 0.22 | 0.23 | 0.25 | 0.30 | 0.36 | 0.30 | 0.39 | 0.51 |
| | etching | | | | | | | | | | | | | |
| | amount | | | | | | | | | | | | | |
| | [mg/cm²] | | | | | | | | | | | | | |
| | | Examples | | | Comparative Examples | | | | | | | | | |
| | | 14 | 15 | 16 | 1 | 2 | 3 | 4 | 5 | 6 | 7 | 8 | 9 | 10 |
| Blended raw materials | | | | | | | | | | | | | | |
| and evaluation items | | | | | | | | | | | | | | |
| (A) | (A-1) | 41.67 | 41 67 | 41.67 | 41.67 | 41.67 | 41.67 | 41.67 | 41.67 | 41.67 | 41.67 | 41.67 | 41.67 | 41.67 |
| | Naphthalene- | | | | | | | | | | | | | |
| | type epoxy | | | | | | | | | | | | | |
| | resin | | | | | | | | | | | | | |
| | (A-2) | 28.33 | 28.33 | 28.33 | 28.33 | 28.33 | 28.33 | 28.33 | 28.33 | 28.33 | 28.33 | 28.33 | 28.33 | 28.33 |
| | Naphthalene- | | | | | | | | | | | | | |
| | type | | | | | | | | | | | | | |
| | phenolic | | | | | | | | | | | | | |
| | curing agent | | | | | | | | | | | | | |
| (B) | (B-1) | | | | | | | | 30 | 30 | 30 | 30 | | |
| | Epoxy | | | | | | | | | | | | | |
| | modified | | | | | | | | | | | | | |
| | acrylic resin | | | | | | | | | | | | | |
| | (Mw: | | | | | | | | | | | | | |
| | 850,000) | | | | | | | | | | | | | |
| | (B-2) | 30 | 30 | 2 | 30 | 30 | 30 | 30 | | | | | 30 | 30 |
| | Epoxy | | | | | | | | | | | | | |
| | modified | | | | | | | | | | | | | |
| | acrylic resin | | | | | | | | | | | | | |
| | (Mw: | | | | | | | | | | | | | |
| | 600,000) | | | | | | | | | | | | | |
| | (B-3) | | | | | | | | | | | | | |
| | Epoxy | | | | | | | | | | | | | |
| | modified | | | | | | | | | | | | | |
| | acrylic resin | | | | | | | | | | | | | |
| | (Mw: | | | | | | | | | | | | | |
| | 250,000) | | | | | | | | | | | | | |
| Curing accelerator | | | | | | | | | | | | | | |
| (imidazole) | | 0.04 | 0.04 | 0.04 | 0.04 | 0.04 | 0.04 | 0.04 | 0.04 | 0.04 | 0.04 | 0.04 | 0.04 | 0.04 |
| (C) | (C-1) | | | | | | | | | | | | | |
| | GPTMS | | | | | | | | | | | | | |
| | surface- | | | | | | | | | | | | | |
| | treated silica | | | | | | | | | | | | | |
| | (C-2) | 100 | 150 | 200 | | | | | | | | | | |
| | MPTMS | | | | | | | | | | | | | |
| | surface- | | | | | | | | | | | | | |
| | treated silica | | | | | | | | | | | | | |
| | (C-3) | | | | | | | | | | | | | |
| | IPTES | | | | | | | | | | | | | |
| | surface- | | | | | | | | | | | | | |
| | treated silica | | | | | | | | | | | | | |
| | (C-4) | | | | | | | | | | | | | |
| | GOTMS | | | | | | | | | | | | | |
| | surface- | | | | | | | | | | | | | |
| | treated silica | | | | | | | | | | | | | |
| | (C-5) | | | | | | | | | | | | | |
| | MOTMS | | | | | | | | | | | | | |
| | surface- | | | | | | | | | | | | | |
| | treated silica | | | | | | | | | | | | | |
| | (C-6) | | | | 50 | 100 | 150 | 200 | | | | | | |
| | SO-25R | | | | | | | | | | | | | |
| | (C-7) | | | | | | | | 50 | 100 | 150 | 200 | | |
| | DTMS | | | | | | | | | | | | | |
| | surface- | | | | | | | | | | | | | |
| | treated silica | | | | | | | | | | | | | |
| | (C-8) | | | | | | | | | | | | 50 | 100 |
| | HTMS | | | | | | | | | | | | | |
| | surface- | | | | | | | | | | | | | |
| | treated silica | | | | | | | | | | | | | |
| Total (part by mass) | | 200 | 250 | 272 | 150 | 200 | 250 | 300 | 150 | 200 | 250 | 300 | 150 | 200 |
| Evaluation | Peak top | 24 | 23 | 24 | 23 | 24 | 24 | 23 | 23 | 25 | 24 | 24 | 23 | 24 |
| of | temperature | | | | | | | | | | | | | |
| physical | satisfying tan | 257 | 256 | 255 | 255 | 255 | 255 | 255 | 240 | 239 | 241 | 241 | 258 | 255 |
| properties | δ ≧0.05 (° C.) | | | | | | | | | | | | | |
| | Elastic | 0.8 | 1.5 | 1.8 | 1.8 | 0.9 | 1.35 | 2.02 | 0.5 | 1.3 | 2.31 | 2.8 | 0.6 | 1.4 |
| | modulus | | | | | | | | | | | | | |
| | [GPa] | | | | | | | | | | | | | |
| | Coefficient of | 5.6 | 5.4 | 5.5 | 6 | 5.7 | 5.7 | 5.7 | 5.8 | 5.7 | 5.5 | 5 | 5.7 | 5 |
| | thermal | | | | | | | | | | | | | |
| | expansion | | | | | | | | | | | | | |
| | [CTE ppm/ | | | | | | | | | | | | | |
| | ° C.] | | | | | | | | | | | | | |
| | Tensile | 21 | 19 | 17 | 24 | 24 | 24 | 24 | 25 | 22 | 19.5 | 16 | 24 | 14 |
| | elongation | | | | | | | | | | | | | |
| | percentage | | | | | | | | | | | | | |
| | [%] | | | | | | | | | | | | | |
| | Peel strength | 0.48 | 0.45 | 0.42 | 0.49 | 0.49 | 0.49 | 0.49 | 0.45 | 0.33 | 0.21 | 0.15 | 0.5 | 0.42 |
| | [kgf/cm²] | | | | | | | | | | | | | |
| | Package | 425 | 426 | 430 | 495 | 465 | 435 | 430 | 440 | 430 | 430 | 432 | 440 | 430 |
| | warpage | | | | | | | | | | | | | |
| | amount [μm] | | | | | | | | | | | | | |
| | Desmear | 0.29 | 0.37 | 0.48 | 0.60 | 0.90 | 1.35 | 2.03 | 0.40 | 0.80 | 1.00 | 1.39 | 0.30 | 0.70 |
| | etching | | | | | | | | | | | | | |
| | amount | | | | | | | | | | | | | |
| | [mg/cm²] | | | | | | | | | | | | | |

As apparent from Table 1, it was confirmed that each Example could reduce the warpage of the package and decrease the desmear etching amount as compared with each Comparative Example.

### REFERENCE SIGNS LIST

1 Prepreg

2 Metal-clad laminate

3 Printed wiring board

4 Resin composition

5 Woven fabric base material

6 Metal foil

7 Patterned conductor

51 Warp thread

52 Weft thread

1. A prepreg comprising:
a resin composition; and
a woven fabric base material,
the resin composition comprising:
(A) at least one of an epoxy resin having a naphthalene skeleton and a phenolic curing agent having a naphthalene skeleton;
(B) a high molecular weight compound having at least structures represented by formulae (1) and (2) or at least a structure represented by the formula (2), no unsaturated bond between carbon atoms, and a weight-average molecular weight of 250,000 to 850,000; and
(C) an inorganic filler subjected to surface treatment with a silane coupling agent represented by a formula (3), 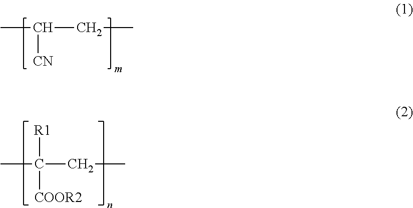
wherein m and n satisfy the following formulae: m:n (molar ratio)=0:1to0.35:0.65; m+n=1; 0≦m≦0.35; and 0.65≦n≦1, and
R1 is a hydrogen atom or a methyl group, and R2 is a hydrogen atom or an alkyl group.
YSiX₃ (3)
wherein X is a methoxy group or an ethoxy group, and Y has a methacryl group, a glycidyl group, or an isocyanate group at a telininal of an aliphatic alkyl group having carbon atoms of 3 or more and 18 or less.

2. The prepreg according to claim 1, wherein a ratio of a loss modulus to a storage modulus is 0.05 or more at a temperature of not more than 60° C. and not less than 200° C. when the prepreg is in a cured state.

3. The prepreg according to claim 1, wherein
a tensile elongation percentage in a 45°-oblique direction with respect to a warp thread or a weft thread of the woven fabric base material is 5% or more when the prepreg is in a cured state.

4. A metal-clad laminate comprising:
the prepreg according to t claim 1; and
a metal foil on the prepreg.

5. A printed wiring board prepared by partially removing the metal foil of the metal-clad laminate according to claim 4 to give a patterned conductor.
